(19) United States
(12) Patent Application Publication
(10) Pub. No.: US 2024/0363825 A1
(43) Pub. Date: Oct. 31, 2024

(54) DRIVING BACKPLANE, LIGHT EMITTING SUBSTRATE, BACKLIGHT MODULE AND DISPLAY APPARATUS

(71) Applicants: Hefei BOE Ruisheng Technology Co., Ltd., Hefei (CN); BOE Technology Group Co., Ltd., Beijing (CN)

(72) Inventors: Chunjian LIU, Beijing (CN); Jian TIAN, Beijing (CN); Jie LEI, Beijing (CN); Yajun MA, Beijing (CN); Jianying ZHANG, Beijing (CN)

(73) Assignees: Hefei BOE Ruisheng Technology Co., Ltd., Hefei (CN); BOE Technology Group Co., Ltd., Beijing (CN)

(21) Appl. No.: 18/769,472

(22) Filed: Jul. 11, 2024

Related U.S. Application Data
(63) Continuation of application No. PCT/CN2022/119979, filed on Sep. 20, 2022.

(51) Int. Cl. H01L 33/62; H01L 25/075; H01L 33/54

(52) U.S. Cl. CPC H01L 33/62; H01L 25/0753; H01L 33/54

(57) ABSTRACT

The present disclosure provides a driving backplane, a light emitting substrate, a backlight module, and a display apparatus, which belongs to the field of display technology. The driving backplane includes a base substrate, a driving layer and an encapsulation layer sequentially laminated. The driving layer has a pad for binding an electronic element and a raised block corresponding to the pad, the pad is located on a side of the corresponding raised block away from the base substrate (BP), and an orthographic projection of the pad on the base substrate is located within an orthographic projection of the corresponding raised block on the corresponding base substrate. The encapsulation layer has a binding opening. The pad and the raised block are located in the binding opening.

### CROSS-REFERENCE TO RELATED APPLICATION

The present application is a Continuation application of International Application No. PCT/CN2022/119979, filed on Sep. 20, 2022, the entire disclosure of which is incorporated herein by reference for all purposes.

### TECHNICAL FIELD

The present disclosure relates to the field of display technology, and more specifically, to a driving backplane, a light emitting substrate, a backlight module and a display apparatus.

### BACKGROUND

Micro light emitting diodes (MLDs) are increasingly widely used in the display field, and may be used, for example, in a backlight module of a liquid crystal display apparatus. Taking a micro light emitting diode light panel of the backlight module as an example, the light panel may include a base substrate, a driving layer, an encapsulation layer, and a micro light emitting diode that are sequentially laminated.

It should be noted that the information disclosed in the above background section is only used to enhance understanding of the background of the present disclosure, and therefore may include information that does not constitute related art known to those of ordinary skill in the art.

### SUMMARY

It is an object of the present disclosure to provide a driving backplane, a light emitting substrate, a backlight module and a display apparatus.

According to a first aspect of the present disclosure, there is provided a driving backplane, including a base substrate, a driving layer and an encapsulation layer sequentially laminated, wherein the driving layer has a pad for binding an electronic element and a raised block corresponding to the pad, the pad is located on a side of the corresponding raised block away from the base substrate, and an orthographic projection of the pad on the base substrate is located within an orthographic projection of the corresponding raised block on the corresponding base substrate, wherein the encapsulation layer has a binding opening, the pad and the raised block are located in the binding opening.

According to an embodiment of the present disclosure, a step height between a surface of the encapsulation layer and a surface of the pad is no more than 0.4 times a maximum thickness of the encapsulation layer.

According to an embodiment of the present disclosure, a dimension of a gap between the encapsulation layer and the pad is less than 7 times a maximum thickness of the encapsulation layer.

According to an embodiment of the present disclosure, a dimension of a gap between the encapsulation layer and the pad is no greater than 1.6 times a maximum thickness of the encapsulation layer.

According to an embodiment of the present disclosure, a thickness of the raised block is between 0.3 times and 0.7 times a maximum thickness of the encapsulation layer.

According to an embodiment of the present disclosure, the raised block is white in color.

According to an embodiment of the present disclosure, a material of the raised block is an organic material doped with reflective particles.

According to an embodiment of the present disclosure, the raised block includes a plurality of sub-film layers sequentially laminated;

in two adjacent sub-film layers of the same raised block, an orthographic projection of a sub-film layer away from the base substrate on the base substrate is located within an orthographic projection of a sub-film layer close to the base substrate on the base substrate.

According to an embodiment of the present disclosure, a plurality of pads electrically connected to the same electronic element are located in the same binding opening.

According to an embodiment of the present disclosure, the driving layer includes a raised layer, a buffer layer, a driving wiring layer, an insulating layer, and a pad layer sequentially laminated on a side of the base substrate;
wherein the raised block is disposed on the raised layer, and the pad is disposed on the pad layer;
wherein the insulating layer has a via hole exposing at least a portion of the driving wiring layer and electrically connected with the pad in one-to-one correspondence, the pad is electrically connected with the driving wiring layer through the via hole.

According to an embodiment of the present disclosure, in at least a portion of the binding openings, the binding opening is provided with one raised block and a plurality of pads; an orthographic projection of each pad on the base substrate is located in an orthographic projection of the raised block on the base substrate.

According to an embodiment of the present disclosure, in at least a portion of the binding openings, the binding opening is provided with a plurality of raised blocks and a plurality of pads;
orthographic projections of at least two of the pads on the base substrate are located in orthographic projections of two different raised blocks on the base substrate respectively.

According to an embodiment of the present disclosure, the pad does not protrude from a surface of the encapsulation layer.

According to an embodiment of the present disclosure, a thickness of the encapsulation layer is not less than 15 μm.

According to an embodiment of the present disclosure, a step height between a surface of the encapsulation layer and a surface of the pad is no more than 12 μm.

According to an embodiment of the present disclosure, a gap between the encapsulation layer and the pad is less than 0.2 mm.

According to an embodiment of the present disclosure, a gap between the encapsulation layer and the pad is not greater than 0.05 mm.

According to an embodiment of the present disclosure, a thickness of the raised block is between 10˜20 μm.

According to an embodiment of the present disclosure, the encapsulation layer is a white encapsulation layer, a black encapsulation layer, or a transparent encapsulation layer.

According to a second aspect of the present disclosure, there is provided a light emitting substrate, including the above driving backplane and an electronic element, wherein the electronic element is electrically connected to the pad through a conductive connection structure.

According to a third aspect of the present disclosure, there is provided a backlight module, including the above light emitting substrate.

According to a fourth aspect of the present disclosure, there is provided a display apparatus, including the above backlight module.

According to a fifth aspect of the present disclosure, there is provided a display apparatus, including the above light emitting substrate, wherein the light emitting substrate is used to display a picture.

It should be understood that the above general description and the following detailed description are only exemplary and explanatory and do not limit the present disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. The drawings in the following description are only some embodiments of the present disclosure, and those skilled in the art can obtain other drawings according to these drawings without creative efforts.

FIG. 1 is a structural schematic diagram of a micro light emitting diode light panel in the related art.

FIG. 2 shows a structural schematic diagram of a driving backplane used by the micro light emitting diode light panel in the related art.

FIG. 3 shows a structural schematic diagram of a driving backplane of a light emitting substrate in an embodiment of the present disclosure.

FIG. 4 shows a structural schematic diagram of a conductive connection structure provided on the driving backplane in an embodiment of the present disclosure.

FIG. 5 shows a structural schematic diagram of a light emitting substrate in an embodiment of the present disclosure.

FIG. 6 shows a structural schematic diagram of a driving backplane of a light emitting substrate in an embodiment of the present disclosure.

FIG. 7 shows a structural schematic diagram of a driving backplane of a light emitting substrate in an embodiment of the present disclosure.

FIG. 8 shows a schematic planar view of the microchip and the driving backplane at a binding position in an embodiment of the present disclosure.

FIG. 9 shows a schematic planar view of the micro light emitting diode and the driving backplane at the binding position in an embodiment of the present disclosure.

FIG. 10 shows a schematic planar view of the micro light emitting diode and the driving backplane at the binding position in another embodiment of the present disclosure.

### DETAILED DESCRIPTION

Example embodiments will now be described more fully with reference to the accompanying drawings. Example embodiments may, however, be embodied in various forms and should not be construed as limited to the embodiments set forth herein; rather, these embodiments are provided so that this disclosure will be thorough and complete and will fully convey the concepts of the example embodiments to those skilled in the art. The same reference numerals in the drawings indicate the same or similar structures, and thus their detailed descriptions will be omitted. Further, the drawings are merely schematic illustrations of the present disclosure and are not necessarily drawn to scale.

Although relative terms such as “up” and “down” are used in this specification to describe the relative relationship of one component of an icon to another, these terms are used in this specification only for convenience, such as in accordance with the orientation of the examples described in the accompanying drawings. It can be understood that if the device of the icon is flipped so that it is upside down, the component described as being “up” will become the component described as being “down”. When a structure is “on” another structure, it may mean that a structure is integrally formed on the other structure, or that a structure is “directly” provided on the other structure, or that a structure is “indirectly” provided on the other structure through another structure.

The terms “a”, “an”, “the”, “said” and “at least one” are used to indicate the presence of one or more elements/components/etc.; the terms “including” and “having” are used to indicate an open-ended inclusive meaning and means that in addition to the listed elements/components/etc., there may be additional elements/components/etc.; the terms “first”, “second”, etc. are used only as markers, no limitation on the number of its objects.

The structural layer A being located on the side of the structural layer B away from the base substrate may be understood that the structural layer A is formed on the side of the structural layer B away from the base substrate. When the structural layer B is a patterned structure, a portion of the structure of the structural layer A may also be located at the same physical height of the structural layer B or at a lower physical height than that of the structural layer B, wherein the base substrate is the height reference.

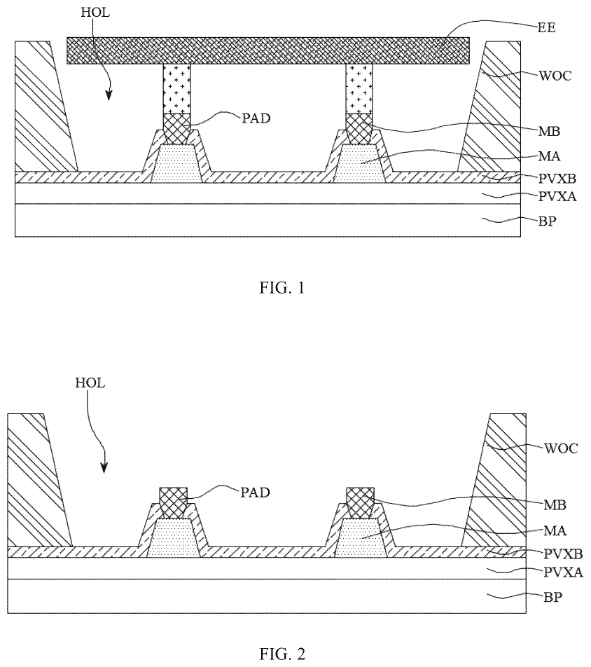

FIG. 1 is a structural schematic diagram of a micro light emitting diode light panel in the related art. FIG. 2 shows a structural schematic diagram of a driving backplane used by the micro light emitting diode light panel in the related art. Referring to FIG. 1, in the related art, the micro light emitting diode light panel includes a base substrate BP, a driving layer, and an electronic element layer EEL which are laminated. The driving layer is provided with a pad PAD and an encapsulation layer WOC, wherein the encapsulation layer WOC has a binding opening HOL exposing the pad PAD. The electronic element layer EEL is provided with a micro light emitting diode as an electronic element EE, and the electronic element EE is bound and connected to the pad PAD through a solder paste.

Referring to FIG. 1, there is a large step height between the surface of the pad PAD and the surface of the encapsulation layer WOC, and the step height is generally more than 20 μm. In order to ensure smooth binding of the electronic element EE to the driving backplane and to avoid interference and blocking of the chip bonding process by the encapsulation layer WOC, the binding opening HOL set by the encapsulation layer WOC needs to be large enough, to allow the electronic element EE to be within the binding opening HOL. In some cases, the spacing between the edge of the binding opening HOL and the pad PAD can be about 0.2 to 1.0 mm. Due to the large size of the binding opening HOL, the adjustment area of light by the packaging layer WOC will be reduced, which in turn imposes constraints on the performance of the micro light emitting diode. Taking a micro light emitting diode light panel as an example of a light panel of a backlight module, the encapsulation layer may adopt a white encapsulation layer, and the white encapsulation layer may reflect the light emitted by the micro light emitting diode, thereby improving the light emitting efficiency of the backlight module. However, the large size of the binding opening HOL set in the white encapsulation layer may reduce the reflective area of the white encapsulation layer, thereby restricting the light emitting efficiency of the micro light emitting diode light panel.

In order to solve the problem caused by the large binding opening of the encapsulation layer, the inventors have made some attempts. For example, while keeping each film layer unchanged, the opening of the binding opening HOL is reduced, so that the opening size of the binding opening HOL is smaller than the size of the electronic element EE, which, however, results in a decrease in the yield of the chip bonding. It was found that this was due to the fact that the encapsulation layer WOC blocked part of the electronic element EE, which made the bonding strength between the part of the electronic element EE and the solder paste insufficient, and in particular, a gap between the part of the electronic element EE and the conductive connecting structure MC may exist, which prevented the bonding of them (i.e., leakage of crystals). Another example is to increase the height of the solder paste while making the opening size of the binding opening HOL smaller than the size of the electronic element EE, so that the solder paste protrudes out of the binding opening HOL to ensure sufficient contact with the electronic element EE, however, this results in the solder paste being too thick, which in turn results in the electronic element EE being prone to tilt.

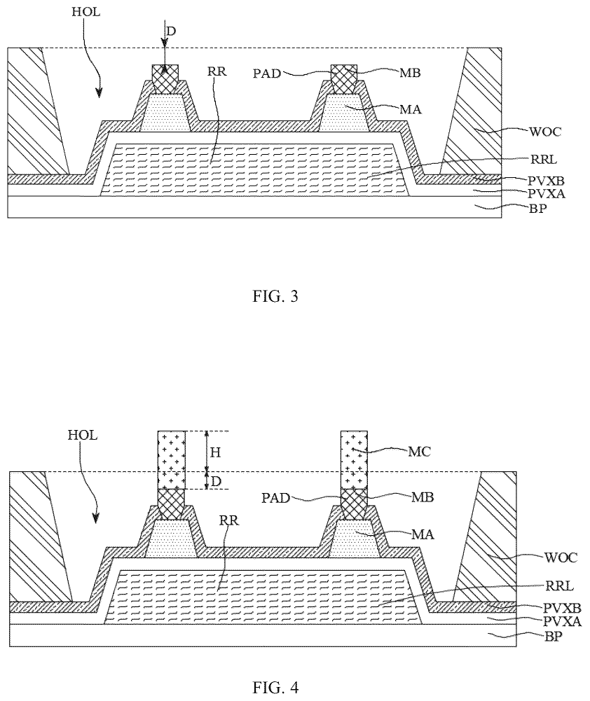

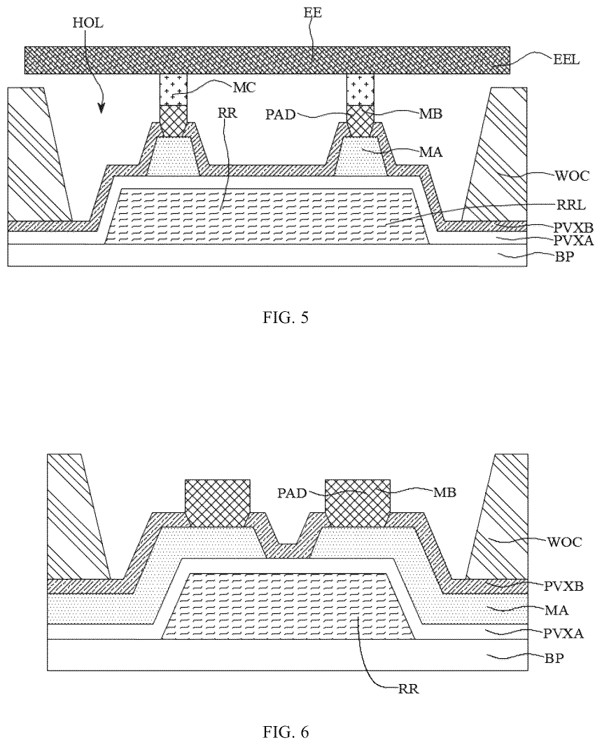

Through various attempts and practical verifications, an embodiment of the present disclosure provides a light emitting substrate. FIG. 3 shows a structural schematic diagram of a driving backplane of a light emitting substrate in an embodiment of the present disclosure. FIG. 4 shows a structural schematic diagram of a conductive connection structure MC provided on the driving backplane. FIG. 5 shows a structural schematic diagram of a light emitting substrate in an embodiment of the present disclosure.

Referring to FIGS. 3 to 5, the light emitting substrate includes a driving backplane and an electronic element layer EEL that are laminated, wherein the driving backplane and the electronic element layer EEL are bound and connected to each other by the conductive connection structure MC.

Referring to FIG. 3, in the embodiment of the present disclosure, the driving backplane includes a base substrate BP, a driving layer and an encapsulation layer WOC that are sequentially laminated. The driving layer has a pad PAD for binding an electronic element EE and a raised block RR corresponding to the pad PAD. The pad PAD is located on a side of the corresponding raised block RR away from the base substrate BP. An orthographic projection of the pad PAD on the base substrate BP is located within an orthographic projection of the corresponding raised block RR on the corresponding base substrate BP. The encapsulation layer WOC has a binding opening HOL. An orthographic projection of the raised block RR on the base substrate BP is located in an orthographic projection of the binding opening HOL on the base substrate BP. The binding opening HOL exposes the pad PAD. Referring to FIG. 5, in the light emitting substrate, the electronic element layer EEL is provided with an electronic element EE, and the electronic element EE is electrically connected to pad PAD through the conductive connection structure MC.

In the electronic element layer of the light emitting substrate, at least part of the electronic element EE is a light emitting element, for example a micro light emitting diode. In the embodiment of the present disclosure, the micro light emitting diode may include, but is not limited to, a Mini Light Emitting Diode (Mini LED) or a Micro Light Emitting Diode (Micro LED). The Mini LED has a size of about 100-300 μm, and the Micro LED has a size of 100 μm or less.

In the driving backplane provided in the embodiments of the present disclosure, by means of the elevating effect of the raised block RR, it is possible to make the distance between the pad PAD and the base substrate BP increase, which in turn makes the step height between the pad PAD and the encapsulation layer WOC decrease. In this way, referring to FIG. 4, by providing the conductive connection structure MC on the driving backplane, the height of the conductive connection structure MC protruding from the encapsulation layer WOC can be increased, which in turn can improve the connection yield between the electronic element EE and the conductive connection structure MC. Since the encapsulation layer WOC will no longer prevent the connection between the electronic element EE and the conductive connection structure MC, the size of the binding opening HOL of the encapsulation layer WOC can be reduced, thereby increasing the coverage area of the encapsulation layer WOC and improving the performance of the light emitting substrate.

In one embodiment of the present disclosure, the encapsulation layer WOC of the driving backplane may be an encapsulation layer having a reflective effect, such as a white encapsulation layer having a reflective effect, or a transparent encapsulation layer having a reflective layer, or a transparent encapsulation layer that does not prevent the reflection of the other film layers of the driving backplane, or the like. In this way, the encapsulation layer WOC can improve the light emitting efficiency of the light emitting substrate by reflecting light or by not preventing the reflection of other film layers (e.g., metal layers or reflective layers, etc.). This makes the light emitting substrate particularly suitable for use as a light source, for example, for a lighting apparatus or for a backlight module of a liquid crystal display panel, or the like. In the embodiment of the present disclosure, since the binding opening HOL of the encapsulation layer WOC can be reduced, the reflective effect of the driving backplane can be improved, which in turn improves the light emitting brightness and efficiency of the light emitting substrate.

In another embodiment of the present disclosure, the encapsulation layer WOC of the driving backplane may be an encapsulation layer with a light absorbing effect, for example, it may be a black encapsulation layer. In this way, the light emitted by the light emitting element may not be reflected by the encapsulation layer, thereby avoiding crosstalk between the emitted light of different light emitting elements. When the light emitting substrate is used directly for displaying a picture, the individual light emitting elements can be used as sub-pixels. The crosstalk between the sub-pixels is reduced, which may improve the quality of the picture, and in particular improve the contrast of the displayed picture. In this embodiment, since the binding opening on the encapsulation layer can be reduced, the light absorbing area of the encapsulation layer can be increased, the light crosstalk between different light emitting elements can be reduced, and the performance of the light emitting substrate can be further improved.

It can be understood that the encapsulation layer of the present disclosure may also be other types of encapsulation layer, whichever is able to improve the performance of the driving backplane and the light emitting substrate by reducing the binding opening. In one embodiment of the present disclosure, a step height between a surface of the encapsulation layer and a surface of the pad is no more than 0.4 times the maximum thickness of the encapsulation layer. For example, the maximum thickness of the encapsulation layer WOC is 30 μm, then the step height between the surface of the encapsulation layer and the surface of the pad is no more than 12 μm.

In another embodiment of the present disclosure, the step height between the surface of the encapsulation layer WOC and the surface of the pad PAD does not exceed 12 μm. In this way, it is possible to reliably bind the electronic element to the pad by using a conductive connection structure of reasonable height.

Referring to FIG. 4, before binding the electronic element EE, it is necessary to provide a conductive connection structure MC (e.g., solder paste) on the pad PAD of the driving backplane, and to make the conductive connection structure MC protrude from the encapsulation layer WOC. In one embodiment of the present disclosure, it may determine the thickness of the conductive connection structure MC (the thickness before binding the electronic element EE) based on the step height D between the pad PAD and the encapsulation layer WOC, so that the step height H between the conductive connection structure MC and the encapsulation layer WOC is not less than 10 μm. In this way, the yield of the electrical connection between the conductive connection structure MC and the electronic element EE can be ensured, it can avoid that a part of the conductive connection structure MC is not able to be effectively electrically connected to the electronic element EE due to the too small amount of the conductive connection structure MC, and the risk of crystal leakage can be reduced. In this embodiment, although the conductive connection structure MC protrudes at least 10 μm from the encapsulation layer WOC, the thickness of the conductive connection structure MC will not be too thick since the step height between the pad PAD and the encapsulation layer WOC is not more than 12 μm, which in turn reduces the risk of the tilting of the electronic element EE.

It can be understood that by adjusting the thickness of the raised block RR, the step height D between the pad PAD and the encapsulation layer WOC can be adjusted. In some embodiments of the present disclosure, the thickness of the raised block RR is set such that the step height between the pad PAD and the encapsulation layer WOC is not greater than 12 μm. In some embodiments, the raised block RR is set such that the step height between the pad PAD and the encapsulation layer WOC is not greater than 10 μm.

In one embodiment of the present disclosure, a thickness of the raised block RR is between 0.3 times and 0.7 times the maximum thickness of the encapsulation layer. For example, if the maximum thickness of the encapsulation layer WOC is 30 μm, the thickness of the raised block RR is 9˜21 μm.

In another embodiment of the present disclosure, the thickness of the raised block RR is 10˜20 μm.

In one embodiment of the present disclosure, the thickness of the encapsulation layer WOC is not less than 15 μm, for example not less than 20 μm. In this way, the encapsulation layer WOC has a large thickness, which avoids the problem of decreasing the reflective ability due to insufficient thickness of the encapsulation layer WOC, and ensures the light emitting efficiency of the light emitting substrate. In one example, the thickness of the encapsulation layer WOC is between 20 μm and 30 μm. In this way, it can also avoid that the thickness of the encapsulation layer WOC is too large, thereby avoiding waste of materials and difficulty in controlling the profile of the encapsulation layer WOC due to the too large thickness of the encapsulation layer WOC, and thereby reducing the cost of the driving backplane and improving the quality of the driving backplane.

In one embodiment of the present disclosure, the encapsulation layer WOC can be formed by printing, such as forming the encapsulation layer WOC by screen printing.

In one embodiment of the present disclosure, referring to FIG. 3, the pad PAD does not protrude from the surface of the encapsulation layer WOC. In other words, the pad PAD is still located within the binding opening HOL of the encapsulation layer WOC. In other embodiments, part of the pad PAD may also protrude from the surface of the encapsulation layer WOC.

In one embodiment of the present disclosure, the dimension of the gap between the encapsulation layer and the pad is less than 7 times the maximum thickness of the encapsulation layer. Further, the dimension of the gap between the encapsulation layer and the pad is not greater than 1.6 times the maximum thickness of the encapsulation layer. In this way, the binding opening can be reduced as much as possible within the range allowed by the process.

In another embodiment of the present disclosure, the gap between the encapsulation layer WOC and the pad PAD is less than 0.2 mm. Compared with related technologies, this can reduce the size of the binding opening HOL, thereby increasing the coverage rate of the encapsulation layer WOC, and improving the performance of the light emitting substrate. In testing, it was found that compared with related technologies, as for the light emitting substrate that uses the encapsulation layer having a reflective effect, the light outputting efficiency can be increased by 1%˜5%. It may be understood that, when the encapsulation layer of the light emitting substrate has a light absorbing effect, the light absorbing efficiency of the encapsulation layer can be improved by 1% to 5%, thereby improving the quality of the display screen. In a further example, the gap between the encapsulation layer WOC and the pad PAD is not greater than 0.05 mm.

In one embodiment of the present disclosure, referring to FIGS. 3 and 5, the pads PADs, which are used for binding with the same electronic element EE, may be located in the same binding opening HOL. In this way, each of the binding openings HOL is disposed in one-to-one correspondence with each of the electronic elements EE, and each of the binding openings HOL exposes individual pad PADs required for the corresponding electronic element EE.

It can be understood that, in other embodiments of the present disclosure, for at least a portion of the electronic element EE, especially for an electronic element EE having a large size, for example, a crossover resistor, the respective pad PADs connected to the electronic element EE may also be located in at least two different binding openings HOL, respectively.

In the light emitting substrate shown in FIG. 5, the electronic element EE may be overlapped with the encapsulation layer WOC, i.e., the dimension of the electronic element EE may be larger than the size of the corresponding binding opening HOL, to minimize the size of the binding opening HOL. It may be understood that in other embodiments of the present disclosure, the dimension of the electronic element EE may also be smaller than the dimension of the binding opening HOL. For example, an orthographic projection of the electronic element EE on the base substrate BP is located within an orthographic projection of the binding opening HOL on the base substrate BP.

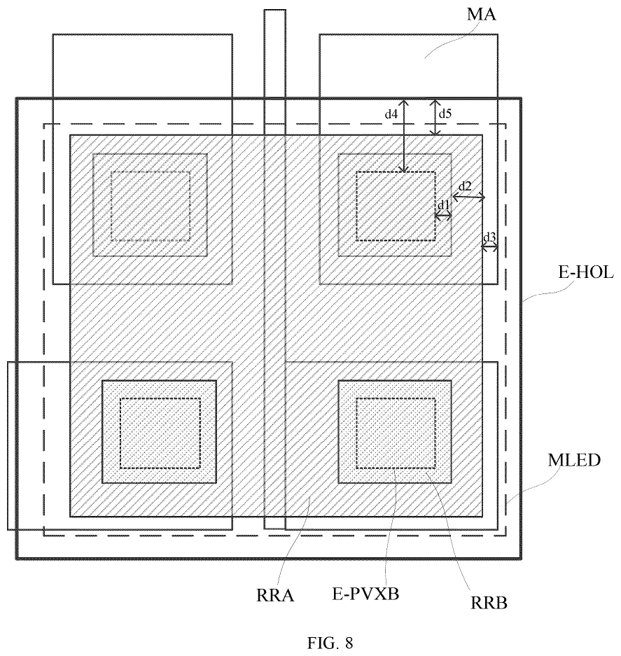

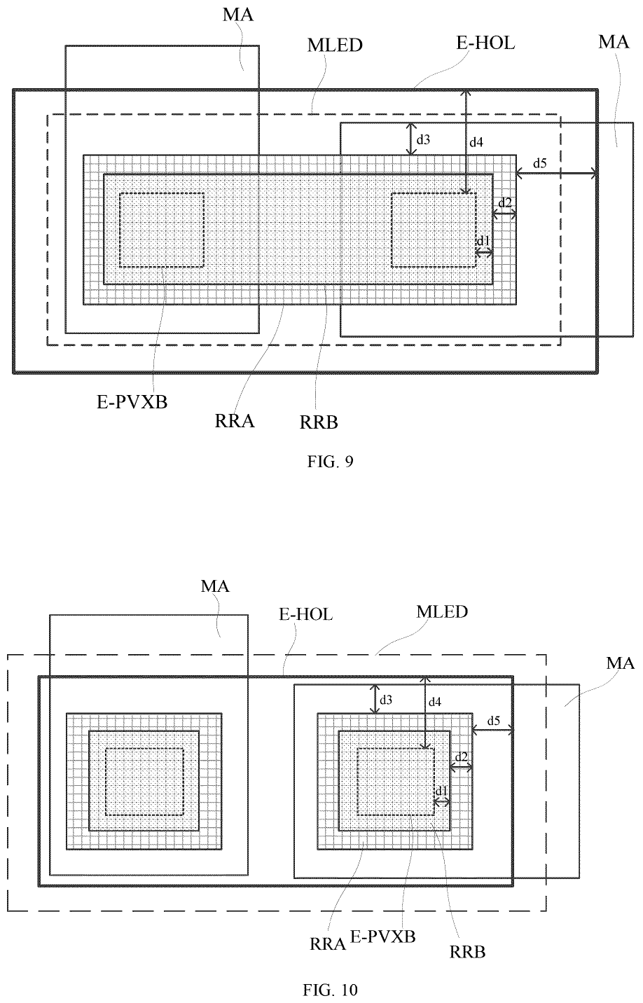

In one embodiment of the present disclosure, referring to FIGS. 8 and 9, in at least part of the binding openings HOL, the binding opening HOL is provided with one raised block RR and a plurality of the pads PADs, and each of the pads PADs is overlapped with the raised block RR. In other words, in at least part of the binding openings HOL, the binding opening is provided with one raised block and a plurality of the pads. An orthographic projection of each pad on the base substrate is located in an orthographic projection of the raised block on the base substrate.

In another embodiment of the present disclosure, referring to FIG. 10, in at least part of the binding openings HOL, a plurality of the raised blocks RR and a plurality of the pads PADs are provided in the binding opening HOL, and at least two of the pads PADs are overlapped with two different raised blocks RR, respectively. In other words, in at least part of the binding openings HOL, the binding opening is provided with one raised block and a plurality of the pads. An orthographic projection of each pad on the base substrate is located in an orthographic projection of the raised block on the base substrate.

In one embodiment of the present disclosure, referring to FIG. 3, the driving layer includes a raised layer RRL, a buffer layer PVXA, a driving wiring layer MA, an insulating layer PVXB, and a pad layer MB sequentially laminated on a side of the base substrate BP.

The raised block RR is disposed on the raised layer RRL, and the pad PAD is disposed on the pad layer MB.

The insulating layer PVXB has a via hole exposing at least a portion of the driving wiring layer MA and electrically connected with the pad PAD in one-to-one correspondence, the pad PAD is electrically connected with the driving wiring layer MA through the via hole. Referring to FIG. 3, the orthographic projection of the via hole of the insulating layer PVXB on the base substrate BP overlaps with the top surface of the raised block RR. In other words, the orthographic projection of the via hole of the insulating layer PVXB on the base substrate BP is located in the orthographic projection of the top surface of the raised block RR on the base substrate. In the embodiment of the present disclosure, overlapping of two structures means that the orthographic projection of one of the structures on the base substrate has an overlapping region with the orthographic projection of the other structure on the base substrate.

In this way, the raised block RR can elevate the overlapping driving wiring layer MA. The insulating layer PVXB is provided with a via hole in one-to-one correspondence with the pad PAD and exposing at least a portion of the driving wiring layer MA, and the pad PAD is electrically connected to the driving wiring layer MA through the via hole. In this way, the effect of elevating the pad PAD by the raised block RR is achieved. The electrical connection between the pad PAD and the driving wiring layer MA can be achieved by only penetrating through the via hole of the insulating layer PVXB, without requiring to penetrate the raised block RR, thereby ensuring the yield between the pad PAD and the driving wiring layer MA, and simplifying the preparation process of the pad PAD.

For example, a raised layer RRL, a buffer layer PVXA, a driving wiring layer MA, and an insulating layer PVXB may be formed sequentially on one side of the base substrate BP. The raised layer RRL, the driving wiring layer MA, and the pad layer MB are patterned film layers, which need to be patterned using a mask plate, respectively. The buffer layer PVXA is a full-area film layer, which does not need to be patterned and can be formed using a deposition process. Then, chemical plating can be utilized to grow the pad PAD in the via hole of the insulating layer PVXB, to cause the pad PAD to protrude from the insulating layer PVXB. In this way, the orthographic projection of the pad PAD on the base substrate BP is substantially consistent with the orthographic projection of the via hole of the insulating layer PVXB on the base substrate BP.

In one example, the pad PAD may include a nickel layer and a gold layer which are sequentially laminated, and a thickness of the nickel layer is greater than that of the gold layer. In this way, re-work of the light emitting substrate is facilitated.

In one example, the thickness of the pad PAD is in the range of 2 to 5 μm, such as in the range of 2.5 to 4.5 μm.

In other embodiments of the present disclosure, the material, structure, thickness, as well as the preparation method of the pad PAD may also be different from the above examples.

In one example, the base substrate BP is a glass substrate, which can reduce the cost of the driving backplane. The base substrate BP may also be made of other materials, such as an acrylic substrate.

In one embodiment of the present disclosure, the material of the buffer layer PVXA may be silicon oxide, silicon nitride, or silicon nitride oxide, which in particular may be silicon oxide. In this way, on the one hand, the adhesion between the driving wiring layer MA and the base substrate BP can be improved, and the risk of peeling off of the driving wiring layer MA can be reduced. On the other hand, this can alleviate the stress exerted by the driving wiring layer MA on the base substrate BP, reduce the damaged risk of the base substrate BP and reduce the degree of warpage of the base substrate BP.

Optionally, a deposition process (e.g., sputtering, vapor phase chemical deposition, etc.) may be used to prepare the buffer layer PVXA.

In one embodiment of the present disclosure, the material of the insulating layer PVXB may be silicon oxide, silicon nitride, or silicon nitride oxide, which in particular may be silicon nitride. In this way, the insulating layer PVXB is dense and insulating, which can effectively protect the driving wiring layer MA.

Optionally, a deposition process (e.g., sputtering, vapor phase chemical deposition, etc.) may be used to form the desired film material of the insulating layer PVXB, and then a photolithographic process (exposure, development, etching) may be used to form the via hole.

The driving wiring layer MA may be a single film layer or may include a plurality of laminated film layers. In one embodiment of the present disclosure, the driving wiring layer MA may be a sandwich conductive structure, which may include a protective layer/conductive metal layer/protective layer sequentially laminated. The material of the protective layer may be a metal or an alloy, to improve the adhesion of the driving wiring layer MA with the other film layers, or to avoid corrosion (e.g., oxidization) of the conductive metal layer, or to avoid diffusion of atoms of the protective metal layer that may affect the structural stability. For example, the driving wiring layer MA may include a titanium layer/aluminum layer/titanium layer, or may include a molybdenum-niobium alloy layer/copper layer/molybdenum-niobium alloy layer. The conductive metal layer may also be made of other metals with high electrical conductivity, to reduce the resistance of the driving wiring layer MA. The protective layer may also adopt other inert metals, alloys or conductive compounds, which for example may adopt nickel-containing alloys, molybdenum-containing alloys, conductive metal oxides (e.g., ITO) or conductive metal nitrides (e.g., titanium nitride).

Optionally, the driving wiring layer MA may be prepared by deposition, photolithographic processes. For example, the desired material layer is formed by a deposition process (e.g., magnetron sputtering), and then the driving wiring layer MA is patterned by a photolithographic process (coating with photoresist, exposing, developing, etching, and removing the photoresist) to form the desired driving traces. It can be understood that other processes may also be employed or other processes may be combined, to prepare the driving wiring layer MA. For example, the driving wiring layer MA may also be prepared by means of the electroplating processes, chemical plating process, etc.

In one embodiment of the present disclosure, the thickness of the driving wiring layer MA is in the range of 1 to 5 μm, for example, in the range of 2.4 μm to 3.0 μm. In this way, the driving wiring layer MA can have a large thickness and a small resistance, reducing the voltage drop across the driving wiring layer MA and meeting the large current demand of the electronic element EE.

In some embodiments of the present disclosure, the raised block RR may have a reflective capability, for example, it may be white in color. In this way, on the one hand, the raised block RR can elevate the pad PAD to facilitate the reduction of the binding opening HOL, and on the other hand, it can also perform a reflective function inside the binding opening HOL, which in turn can further improve the light emitting efficiency of the light emitting substrate.

In one example, the material of the raised block RR is an organic material doped with reflective particles, such as an organic resin doped with titanium dioxide nanoparticles.

In one example, the thickness of the raised block RR is not less than 10 μm, such as between 13 and 18 μm. In this way, on the one hand, the pad PAD can be sufficiently elevated, and on the other hand, the raised block RR is sufficiently thick for reflecting. By way of example, the raised block RR is white in color and has a thickness of 15 μm.

For example, in one embodiment of the present disclosure, the encapsulation layer is an encapsulation layer having a reflective capability (e.g., an encapsulation layer using white oil as a material); and the raised block RR is a white raised block having a reflective capability.

It is to be understood that, in some other embodiments of the present disclosure, the raised block may be a raised block having a light absorbing effect. For example, when the encapsulation layer is a raised block having a light absorbing effect, the raised block may be a black raised block having a light absorbing effect.

In other embodiments of the present disclosure, the raised block may also be of other colors, for example, it may be a transparent raised block.

Referring to FIG. 6, the driving wiring layer MA needs to climb along the side of the raised block RR to the top of the raised block RR, in order to be electrically connected to the pad PAD through the via hole at the top of the raised block RR. This requires that the side of the raised block RR has a suitable climbing profile, such as having a suitable slope angle or a suitable climbing step height, to avoid the driving wiring layer MA from breaking during the climbing process.

In one example, a photolithographic process may be used to prepare the raised block RR, so as to make the surface profile of the raised block RR stable and flat, as well as to effectively control the side profile of the raised block RR. In this way, the profile and position of the driving wiring layer MA can be ensured, and in particular, the breaking of the driving wiring layer MA at the side of the raised block RR can be avoided.

It can be understood that the slope of the side of the prepared raised block RR may be different by using different organic materials and photolithographic processes. When the slope of the side of the raised block RR is too steep which is unfavorable for electrical continuity of the driving wiring layer MA, the shoulder step may be prepared at the side of the raised block RR to reduce the climbing step height for each climb of the driving wiring layer MA.

In one embodiment of the present disclosure, the raised block RR only includes one film layer, for example, an organic material layer having reflective particles. The slope angle of the side of the raised block RR can be controlled, so that the driving wiring layer MA does not break during the climb. By way of example, the slope angle of the side of the raised block RR may be in the range of 40° to 60°. It can be understood that the slope angle of the side of the raised block RR may be further reduced, for example, the slope angle is in the range of 25° to 35°, to ensure that the driving wiring layer MA does not break under a large climbing step height. In this embodiment, on the one hand, it is possible to prepare the desired raised block RR with only one patterning process (using a single mask), and on the other hand, it is also possible to further improve the light emitting efficiency of the light emitting substrate by means of the reflective properties of the raised block RR itself.

In other embodiments of the present disclosure, the raised block RR includes a plurality of sub-film layers that are sequentially laminated, which may include, for example, two sub-film layers or three sub-film layers that are sequentially laminated. The dimension of each of the sub-film layers sequentially decreases along a direction away from the base substrate BP. In other words, the orthographic projection of a sub-film layer away from the base substrate BP on the base substrate BP is located within the orthographic projection of a sub-film layer close to the base substrate BP on the base substrate BP. In this way, it is possible to form a shoulder step at the side of the raised block RR, so that the driving wiring layer MA climbs one sub-film layer at one time during the climb, which reduces the claiming step height for each climb, and thus reducing the risk of breaking of the driving wiring layer MA during the climb. In this embodiment, the material of each sub-film layer may be a white material or a material of another color, for example, it may be a colorless and transparent material.

In one example, the material of each sub-film layer is an organic material, for example, it may be an organic resin material. In this way, by increasing the thickness of the sub-film layer or preparing a thick sub-film layer, the raised block RR can have a large thickness, to elevate the pad PAD.

In one example, a photolithographic process may be used to prepare respective sub-film layers, to ensure that the sides of respective sub-film layers have a good profile and a suitable slope angle, to avoid breaking of the driving wiring layer MA due to the slope angle being too large.

Optionally, individual sub-film layers may be prepared one by one by using a photolithographic process, such as using two photolithographic processes to prepare two sub-film layers respectively. In other embodiments of the present disclosure, the desired individual sub-film layers may also be prepared using a gray-scale mask process during a single photolithographic process.

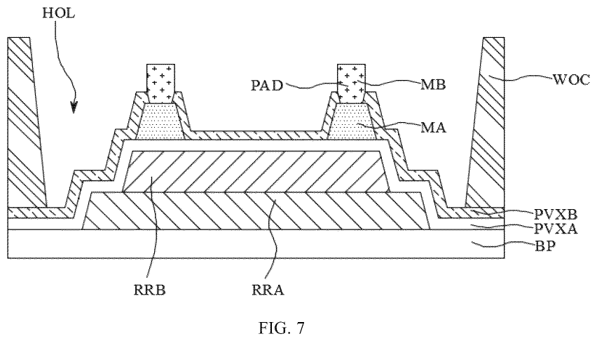

In one example, referring to FIG. 7, the raised block RR includes two sub-film layers, i.e., a first raised sub-film layer RRA and a second raised sub-film layer RRB, which are sequentially laminated on one side of the base substrate BP. In this way, an orthographic projection of the second raised sub-film layer RRB on the base substrate BP is located within the orthographic projection of the first raised sub-film layer RRA on the base substrate BP.

In one example, the first raised sub-film layer RRA and the second raised sub-film layer RRB have the same thickness.

In one example, the first raised sub-film layer RRA and the second raised sub-film layer RRB have the same material.

In one example, a shoulder step is formed between the first raised sub-film layer RRA and the second raised sub-film layer RRB, which is beneficial to keep the driving wiring layer MA climbing on the side of the raised block RR electrically continuous. In other words, the bottom end surface (the end surface close to the base substrate BP) of the second raised sub-film layer RRB is smaller than the size of the top end surface (the end surface away from the base substrate BP) of the first raised sub-film layer RRA, and there is a gap between the edges of them two. At least a portion of the top surface of the first raised sub-film layer RRA is not covered by the second raised sub-film layer RRB. This may reduce the step height each time the driving wiring layer MA climbs, and reduce the risk of breaking of the driving wiring layer MA.

The electronic element layer EEL includes an electronic element EE electrically connected to the driving backplane. The electronic element EE has pins, and the pins of the electronic element EE are electrically connected to the corresponding pads PADs through the conductive connection structure MC. In one embodiment of the present disclosure, the conductive connection structure MC is a solder paste, so that the electrical connection between the electronic element EE and the pad PAD can be achieved by processes such as coating a solder paste (e.g., printing a solder paste), mounting the electronic element EE (chip bonding), and reflow soldering. It may be understood that, the conductive connection structure MC may also adopt other structures or materials. For example, in some other embodiments, the conductive connection structure MC may also be an electrically conductive adhesive, or a spike-like concave-convex structure composed of a hard metal.

In one embodiment of the present disclosure, the electronic element EE includes a light emitting element, for example, an LED lamp bead, a Mini LED or a Micro LED, etc., or other current-driven light emitting elements. The light emitting element has a pin for binding to a pad PAD. The pin is bound to a corresponding pad PAD via a conductive connection structure MC.

In FIGS. 9 and 10, a schematic diagram of a planar structure of a localized position of a light emitting substrate is shown using a micro light emitting diode MLED as the light emitting element. FIG. 9 shows a schematic planner view of the micro light emitting diode MLED and the driving backplane at the binding position in an example of the embodiment of the present disclosure. FIG. 10 shows a schematic plan view of the micro light emitting diode MLED and the driving backplane at the binding position in an example of the embodiment of the present disclosure. It can be understood that FIGS. 9 and 10 are only examples with the micro light emitting diode MLED as the light emitting element. In other embodiments of the present disclosure, the light emitting element may also be other electronic elements.

In FIGS. 9 and 10, only relative relationships between the first raised sub-film layer RRA, the second raised sub-film layer RRB, the driving wiring layer MA, the via hole edge E-PVXB of the insulating layer PVXB, the edge E-HOL of the binding opening HOL, and the edge of the micro light emitting diode MLED, etc., are shown, and the pad PAD is not shown. The position of the pad PAD is the same as that of the via hole of the corresponding insulating layer PVXB.

Referring to FIGS. 9 and 10, the electronic element EE includes a micro light emitting diode MLED as a light emitting element. The micro light emitting diode MLED has an anode pin and a cathode pin. The driving backplane is provided with a group of light source pads in one-to-one correspondence with the micro light emitting diodes MLED. Each group of light source pads includes two pads PADs disposed in the same binding opening HOL. The two pads PADs are electrically connected to the anode pin and the cathode pin of the micro light emitting diode MLED respectively through the conductive connection structure MC. In the example of FIG. 9, a raised block RR is provided in the binding opening HOL. Two pads PADs in the binding opening HOL are disposed on the raised block RR. In the example of FIG. 10, two raised blocks RR are provided in the binding opening HOL. Two pads PADs in the binding opening HOL are disposed on the two raised blocks RR respectively.

In the example of FIGS. 9 and 10, the spacing d1 between the edge of the orthographic projection of the opening of the insulating layer PVXB on the base substrate BP and the edge of the orthographic projection of the second raised sub-film layer RRB on the base substrate BP may be between 10 to 15 μm, for example, which may be 13 μm. The spacing d2 between the edge of the orthographic projection of the second raised sub-film layer RRB on the base substrate BP and the edge of the orthographic projection of the first raised sub-film layer RRA on the base substrate BP may be between 10 to 15 μm, for example, which may be 12 μm. The driving wiring layer MA has a driving trace, and the driving trace climbs along a side of the raised block RR to the top of the raised block RR. A width of the driving trace is greater than a width of the raised block RR. Along the width direction of the driving trace, a spacing d3 between an edge of the orthographic projection of the first raised sub-film layer RRA on the base substrate BP and an edge of the orthographic projection of the driving trace on the base substrate BP can be in the range of 15 to 25 μm, for example, which may be 20 μm. The spacing d4 between the edge of the orthographic projection of the opening of the insulating layer PVXB on the base substrate BP and the edge of the orthographic projection of the binding opening HOL on the base substrate BP may be between 35 to 65 μm, for example, which may be 50 μm. The spacing d5 between the edge of the orthographic projection of the first raised sub-film layer RRA on the base substrate BP and the edge of the orthographic projection of the binding opening HOL on the base substrate BP may be between 10 to 40 μm, for example, which may be 25 μm.

In one example, the driving traces connected to the two pads PADs are insulated from each other, for applying the anode voltage and the cathode voltage respectively. In the example, the spacing between the driving traces connected to the pads PADs may be between 50 and 100 μm.

In the example of FIG. 9, the dimension of the micro light emitting diode MLED is smaller than the dimension of the binding opening HOL, and the orthographic projection of the micro light emitting diode MLED on the base substrate BP is located within the orthographic projection of the binding opening HOL on the base substrate BP.

In the example of FIG. 10, the dimension of the micro light emitting diode MLED is larger than the dimension of the binding opening HOL, and the orthographic projection of the binding opening HOL on the base substrate BP is located within the orthographic projection of the micro light emitting diode MLED on the base substrate BP.

In one embodiment of the present disclosure, the dimension of the micro light emitting diode MLED does not exceed 300 μm.

It can be understood that, the examples of FIGS. 9 and 10, and in particular the dimensions described, are merely illustrative for the purpose of further illustrating the specific principles and effects of embodiments of the present disclosure. In other embodiments of the present disclosure, the structure and dimension of the light emitting substrate at the group of light source pads may also be other structures and dimensions that can meet the requirements, as long as the raised block RR is able to elevate the pad PAD to reduce the step height between the pad PAD and the encapsulation layer WOC.

In some embodiments of the present disclosure, referring to FIG. 8, the electronic element EE may also include a microchip MIC for driving the light emitting substrate. The microchip MIC includes a plurality of pins, for example, including 4 to 10 pins. The driving backplane is provided with a group of driving pads in one-to-one correspondence with respective microchips MIC, and each group of driving pads includes a plurality of pads PADs in one-to-one correspondence with respective pins of the microchip MIC. The pins of the microchip MIC are electrically connected to the corresponding pads PADs through the conductive connection structure MC. The driving wiring layer MA may send a driving signal to the microchip MIC, and the microchip MIC drives respective micro light emitting diodes MLEDs according to the driving signal. When the microchip MIC makes the micro light emitting diode MLED in an electrical circuit, the micro light emitting diode MLED may emit light. When the microchip MIC makes the micro light emitting diode MLED in an electrical circuit break, the micro light emitting diode MLED does not emit light.

FIG. 8 shows a planar view of the microchip MIC and the driving backplane at a binding position in an example of an embodiment of the present disclosure. In FIG. 8, only the relative relationship between the first raised sub-film layer RRA, the second raised sub-film layer RRB, the driving wiring layer MA, the via hole edge E-PVXB of the insulating layer PVXB, the edge E-HOL of the binding opening HOL, and the edge of the microchip MIC, or the like, is shown, and the pad PAD is not shown. The position of the pad PAD is the same as the position of the via hole of the corresponding insulating layer PVXB. In the example of FIG. 8, individual pads PADs of the group of the driving pads are located in the same binding opening HOL. In the example of FIG. 8, only one raised block RR is provided in the binding opening HOL, and the individual pads PADs of the group of the driving pads are located on the same raised block RR.

In the example of FIG. 8, a spacing d1 between an edge of the orthographic projection of the opening of the insulating layer PVXB on the base substrate BP and an edge of the orthographic projection of the second raised sub-film layer RRB on the base substrate BP may be between 10 to 15 μm, for example, which may be 13 μm. The spacing d2 between the edge of the orthographic projection of the second raised sub-film layer RRB on the base substrate BP and the edge of orthographic projection of the first raised sub-film layer RRA on the base substrate BP may be between 10 to 15 μm, for example, which may be 12 μm. The driving wiring layer MA has a driving trace, and the driving trace climbs along a side of the raised block RR to the top of the raised block RR. The width of the driving trace is greater than the width of the raised block RR. Along the width direction of the driving trace, the spacing d3 between the edge of the orthographic projection of the first raised sub-film layer RRA on the base substrate BP and the edge of the orthographic projection of the driving trace on the base substrate BP can be in the range of 5 to 25 μm, for example, which may be 10 μm. The spacing d4 between the edge of the orthographic projection of the opening of the insulating layer PVXB on the base substrate BP and the edge of the orthographic projection of the binding opening HOL on the base substrate BP may be between 35 to 65 μm, for example, which may be 50 μm. The spacing d5 between the edge of the orthographic projection of the first raised sub-film layer RRA on the base substrate BP and the edge of the orthographic projection of the binding opening HOL on the base substrate BP may be between 10 to 40 μm, for example, which may be 25 μm.

In one example, the driving traces connected to the two pads PADs are insulated from each other, for applying the anode voltage and the cathode voltage, respectively. In the example, the spacing between the driving traces connected to the pads PADs may be between 50 and 100 μm.

In one example, there may be other wirings penetrating the pads of the group of driving pads, such as a power supply wiring. In one example, the spacing between the power supply wiring and the wirings connected to the other pad PADs may be between 10 to 20 μm, for example, which may be 17 μm.

In the example of FIG. 10, the size of the microchip MIC is smaller than that of the binding opening HOL, and the orthographic projection of the microchip MIC on the base substrate BP is located within the orthographic projection of the binding opening HOL on the base substrate BP.

In one embodiment of the present disclosure, the design thickness of the conductive connection structure MC may be determined based on a range of fluctuations in the step height D between the pad PAD and the encapsulation layer WOC due to process reasons, and a range of fluctuations in the thickness (or height) of the conductive connection structure MC due to process reasons. When the driving backplane is prepared, the thickness of the pad PAD itself and film layers below the pad PAD has a certain range of fluctuations due to process reasons. The designed amount of height between the PAD pad and the base substrate BP and the fluctuation range can be determined according to the accumulation of the designed amount of thickness of each film layer and the fluctuation range. When preparing the encapsulation layer WOC, the encapsulation layer WOC itself also has a certain thickness fluctuation range, i.e., it has a designed amount and fluctuation range. Based on the designed amount of thickness and the fluctuation range of the encapsulation layer WOC, and the designed amount of height between the pad PAD and the base substrate BP and the fluctuation range, the designed amount of step height D between the pad PAD and the encapsulation layer WOC and the fluctuation range can be determined. Correspondingly, when the conductive connection structure MC is provided, the conductive connection structure MC also has a designed amount and a fluctuation range, and therefore has a thickness fluctuation range.

In one example, a designed amount of the conductive connection structure MC may be determined according to the objective of ensuring that a step height between the conductive connection structure MC and the encapsulation layer WOC is not less than 10 μm. For example, a lower limit of thickness of the conductive connection structure MC may be determined based on a minimum value of the step height D, such that when the conductive connection structure MC has a thickness being the lower limit of thickness, the step height D is still not less than 10 μm, for example, being 10 μm or between 10 and 12 μm. Then, based on the lower limit of thickness of the conductive connection structure MC and the fluctuation range of the conductive connection structure MC, the designed amount of thickness and the fluctuation range of the conductive connection structure MC are determined.

In the following, an example is used to explain and illustrate the design method of the light emitting substrate in the embodiment of the present disclosure.

In the example, the driving backplane includes a base substrate BP, a first raised sub-film layer RRA, a second raised sub-film layer RRB, a buffer layer PVXA, a driving wiring layer MA, an insulating layer PVXB, a pad PAD, and an encapsulation layer WOC, which are sequentially laminated. The first raised sub-film layer RRA has a thickness of 7.5±0.75 μm, the second raised sub-film layer RRB has a thickness of 7.5±0.75 μm, the buffer layer PVXA has a thickness of 0.24±0.02 μm, the driving wiring layer MA has a thickness of 2.76±0.27 μm, the insulating layer PVXB has a thickness of 0.24±0.02 μm; the pad PAD has a thickness of 3.5±1 μm, the encapsulation layer WOC has a thickness of 25±5 μm. Thus, the distance between the surface of the pad PAD and the base substrate BP is 21.74±2.81 μm, and the distance between the surface of the encapsulation layer WOC and the base substrate BP is 25.48±5.04 μm. The above dimensions are denoted as a±b, wherein a is a typical value and b is a fluctuation range due to the process fluctuation and deviation. For any specific product, the specific dimensions are in the range of a−b˜a+b.

As a comparative example, if no raised block RR is provided, the distance between the surface of the pad PAD and the surface of the base substrate BP is 6.74±1.31 μm. In this comparative example, the typical value of the step height D between the surface of the pad PAD and the surface of the encapsulation layer WOC is 25.48 μm−6.74 μm=18.74 μm. The encapsulation layer WOC may affect the chip bonding between the electronic element EE and the electrically conductive connecting structure MC, if the opening of the binding opening HOL is not greatly expanded.

In this example, the typical value of the step height D between the surface of the pad PAD and the surface of the encapsulation layer WOC is 25.48 μm−21.74 μm=3.74 μm. Therefore, the step height D between the surface of the pad PAD and the surface of the encapsulation layer WOC is substantially reduced, which facilitates the conductive connection structure MC to protrude a high distance from the surface of the encapsulation layer WOC, so that the encapsulation layer WOC will not affect the chip bonding between the pad PAD and the conductive connection structure MC, which in turn enables the spacing between the binding opening HOL and the pad PAD to be very small. Considering the limit cases, the minimum distance between the surface of the pad PAD and the surface of the base substrate BP is 21.74 μm−2.81 μm=18.93 μm, and the maximum distance between the surface of the encapsulation layer WOC and the surface of the base substrate BP is 25.48 μm±5.04 μm=30.52 μm; the maximum value of the step height D between the surface of the encapsulation layer WOC and the surface of the pad PAD is 30.52 μm−18.93 μm=11.59 μm. At this time, in order to make the conductive connection structure MC (before binding the electronic element EE) protrude from the surface of the encapsulation layer WOC not less than 10 μm, the thickness of the conductive connection structure MC is at least 11.59 μm±10 μm=21.59 μm. In other words, within the fluctuation range of the thickness of the conductive connection structure MC, it is necessary to make the lower limit of the thickness of the conductive connection structure MC not less than 21.59 μm. In the example, the lower limit of the thickness of the conductive connection structure MC may be made to be 22 μm. If the thickness fluctuation of the conductive connection structure MC is 10 μm above and below a typical value, the thickness of the conductive connection structure MC may be 32 μm #10 μm. In other words, the thickness of the conductive connection structure MC is in the range of 22 μm to 42 μm. Within this range, the conductive connection structure MC may protrude from the surface of the encapsulation layer WOC at least 10 μm, while avoiding an increased risk of tilting of the electronic element EE due to too large thickness of the conductive connection structure MC.

The comparison with the comparative example continues. If the comparative example adopts a similar thickness design of the conductive connection structure MC, for example, the thickness of the conductive connection structure MC is 30 μm±10 μm, then after a considerable proportion of the driving backplanes is provided with the conductive connection structure MC, the conductive connection structure MC is only able to slightly protrude from the surface of the encapsulation layer WOC, which cannot satisfy the requirement of binding the electronic element EE. If the thickness of the conductive connection structure MC is increased, for example, the thickness of the conductive connection structure MC is increased to 50 μm±10 μm, this will result in the thickness of the conductive connection structure MC being large, and the electronic element EE is prone to tilt when it is bound.

Therefore, the driving backplane provided by the embodiments of the present disclosure is able to ensure that the electronic element EE and the conductive connection structure MC can be in reliable chip bonding and reduce the risk of crystal leakage, and at the same time reduce the risk of the tilting of the electronic element EE when being bound, while taking into account the fluctuation of the preparation process. Most importantly, while simultaneously satisfying the above conditions, it is also possible to make the opening of the binding opening HOL smaller, thereby improving the coverage rate of the encapsulation layer WOC, improving the reflective ability of the encapsulation layer WOC, and thereby improving the light emitting efficiency of the light emitting substrate.

In the above example, the raised block RR has a first raised sub-film layer RRA and a second raised sub-film layer RRB, and the pad PAD is elevated by 15 μm. It may be understood that the raised block RR may be a one-layer structure and the pad PAD is elevated by 15 μm. For example, the raised block RR may be a resin containing reflective particles, or it may have more sub-film layers, for example, it may have three sub-film layers. The raised block RR may also elevate the pad PAD by other heights, such as 12 μm, 18 μm, or 20 μm.

In the embodiments of the present disclosure, the provided light emitting substrate can be used as a light panel for a backlight module, a light panel for a lighting apparatus, a light panel for a billboard, a light panel for a signage, and the like. In some cases, the light emitting substrate can also be used as a display panel of a display apparatus capable of direct display. The light emitting substrate provided by embodiments of the present disclosure can also be used in other fields where a light source is required.

The embodiments of the present disclosure also provide a backlight module that includes any one of the light emitting substrates described in the above embodiments of the light emitting substrate. The backlight module may be a backlight module for a smartphone screen, a backlight module for a smartwatch screen, a backlight module for an LCD television set, or a backlight module for other types of liquid crystal display apparatuses. Since the backlight module has any of the light emitting substrates described in the above light emitting substrate embodiments, it has the same beneficial effect, which will not be elaborated by the present disclosure herein.

Embodiments of the present disclosure also provide a display apparatus that includes any one of the backlight modules described in the above-described backlight module embodiments. The display apparatus may be a smartphone screen, a smartwatch screen, or another type of liquid crystal display apparatus. Since the display apparatus has any one of the backlight modules described in the above backlight module embodiments, it has the same beneficial effect, which will not be elaborated by the present disclosure herein.

Other embodiments of the present disclosure will be readily apparent to those skilled in the art from consideration of the specification and practice of the disclosure disclosed herein. This application is intended to cover any modification, use or adaptation of the present disclosure, and these modifications, uses or adaptations follow the general principles of the present disclosure and include common knowledge or conventional technical means in the technical field not disclosed in the present disclosure. The specification and embodiments are to be considered exemplary only, with the true scope and spirit of the disclosure indicated by the appended claims.

What is claimed is:

1. A driving backplane, comprising a base substrate, a driving layer and an encapsulation layer sequentially laminated, wherein the driving layer has a pad for binding an electronic element and a raised block corresponding to the pad, the pad is located on a side of the corresponding raised block away from the base substrate, and an orthographic projection of the pad on the base substrate is located within an orthographic projection of the corresponding raised block on the corresponding base substrate,
wherein the encapsulation layer has a binding opening, an orthographic projection of the raised block on the base substrate is located in an orthographic projection of the binding opening on the base substrate, the binding opening exposes the pad.

2. The driving backplane according to claim 1, wherein a step height between a surface of the encapsulation layer and a surface of the pad is no more than 0.4 times a maximum thickness of the encapsulation layer.

3. The driving backplane according to claim 1, wherein a dimension of a gap between the encapsulation layer and the pad is less than 7 times a maximum thickness of the encapsulation layer.

4. The driving backplane according to claim 1, wherein a dimension of a gap between the encapsulation layer and the pad is no greater than 1.6 times a maximum thickness of the encapsulation layer.

5. The driving backplane according to claim 1, wherein a thickness of the raised block is between 0.3 times and 0.7 times a maximum thickness of the encapsulation layer.

6. The driving backplane according to claim 1, wherein the raised block is white in color.

7. The driving backplane according to claim 1, wherein a material of the raised block is an organic material doped with reflective particles.

8. The driving backplane according to claim 1, wherein the raised block comprises a plurality of sub-film layers sequentially laminated;
in two adjacent sub-film layers of the same raised block, an orthographic projection of a sub-film layer away from the base substrate on the base substrate is located within an orthographic projection of a sub-film layer close to the base substrate on the base substrate.

9. The driving backplane according to claim 1, wherein a plurality of pads electrically connected to the same electronic element are located in the same binding opening.

10. The driving backplane according to claim 1, wherein the driving layer comprises a raised layer, a buffer layer, a driving wiring layer, an insulating layer, and a pad layer sequentially laminated on a side of the base substrate;
wherein the raised block is disposed on the raised layer, and the pad is disposed on the pad layer;
wherein the insulating layer has a via hole exposing at least a portion of the driving wiring layer and electrically connected with the pad in one-to-one correspondence, the pad is electrically connected with the driving wiring layer through the via hole.

11. The driving backplane according to claim 1, wherein in at least a portion of the binding openings, the binding opening is provided with one raised block and a plurality of pads; an orthographic projection of each pad on the base substrate is located in an orthographic projection of the raised block on the base substrate.

12. The driving backplane according to claim 1, wherein in at least a portion of the binding openings, the binding opening is provided with a plurality of raised blocks and a plurality of pads;
orthographic projections of at least two of the pads on the base substrate are located in orthographic projections of two different raised blocks on the base substrate respectively.

13. The driving backplane according to claim 1, wherein the pad does not protrude from a surface of the encapsulation layer.

14. The driving backplane according to claim 1, wherein a thickness of the encapsulation layer is not less than 15 μm.

15. The driving backplane according to claim 1, wherein a step height between a surface of the encapsulation layer and a surface of the pad is no more than 12 μm.

16. The driving backplane according to claim 1, wherein a gap between the encapsulation layer and the pad is less than 0.2 mm.

17. The driving backplane according to claim 1, wherein a gap between the encapsulation layer and the pad is not greater than 0.05 mm.

18. The driving backplane according to claim 1, wherein a thickness of the raised block is between 10˜20 μm.

19. The driving backplane according to claim 1, wherein the encapsulation layer is a white encapsulation layer, a black encapsulation layer, or a transparent encapsulation layer.

20. A light emitting substrate, comprising a driving backplane and an electronic element, wherein the electronic element is electrically connected to the pad through a conductive connection structure,
wherein the driving backplane comprises a base substrate, a driving layer and an encapsulation layer sequentially laminated, wherein the driving layer has a pad for binding an electronic element and a raised block corresponding to the pad, the pad is located on a side of the corresponding raised block away from the base substrate, and an orthographic projection of the pad on the base substrate is located within an orthographic projection of the corresponding raised block on the corresponding base substrate,
wherein the encapsulation layer has a binding opening, an orthographic projection of the raised block on the base substrate is located in an orthographic projection of the binding opening on the base substrate, the binding opening exposes the pad.
